(19) United States
(12) Patent Application Publication
(10) Pub. No.: US 2014/0339179 A1
(43) Pub. Date: Nov. 20, 2014

(54) PHOTOVOLTAIC MODULE FRAME

(71) Applicant: Zep Solar LLC, San Rafael, CA (US)

(72) Inventors: Jack Raymond West, San Rafael, CA (US); Peter Edward Gruber, San Rafael, CA (US); Nathaniel Taylor Coleman, San Rafael, CA (US)

(21) Appl. No.: 14/451,781

(22) Filed: Aug. 5, 2014

Related U.S. Application Data
(63) Continuation-in-part of application No. 14/106,189, filed on Dec. 13, 2013.
Application No. 14/106,189 is a continuation-in-part of application No. 13/351,397, filed on Jan. 17, 2012.
Application No. 13/351,397 is a continuation of application No. 12/594,935, filed on Oct. 6, 2009, now Pat. No. 8,109,048.
(60) Provisional application No. 61/737,076, filed on Dec. 13, 2012.
(60) Provisional application No. 61/864,637, filed on Aug. 12, 2013.

(51) Int. Cl. H01L 31/048; H01L 31/042

(52) U.S. Cl. CPC H01L 31/048; H01L 31/0424
USPC 211/41.1

(57) ABSTRACT

A photovoltaic module frame having hollow sections into which male ends of a corner key are received such that two frame sections can be connected together in orthogonal directions. The male ends of the corner key may have teeth thereon. Once so engaged, a tool head may be applied to the corner formed by the adjacent frame sections. The tool head may create indentations in the profiles that engage the teeth of the corner keys within the frame sections, thereby forming a corner of a module frame.

### CROSS REFERENCES

The present application is a continuation-in-part of application Ser. No. 14/106,189, filed Dec. 13, 2013, which claims the benefit of Provisional Application Ser. No. 61/737,076, filed Dec. 13, 2012. application Ser. No. 14/106,189, filed Dec. 13, 2013 is in turn a continuation-in-part of application Ser. No. 13/351,397, filed Jan. 12, 2012, which is a continuation of application Ser. No. 12/594,935 filed Oct. 2, 2009, now Pat. No. 8,109,048, issued Feb. 7, 2012.

The present application also claims the benefit of Provisional Application Ser. No. 61/864,637, filed Aug. 12, 2013.

### BACKGROUND

Photovoltaic (“PV”) modules are typically comprised of a laminate containing photovoltaic cells and internal wiring with aluminum extrusions (or other fabrication material(s), including composites and/or combinations of materials), located on the perimeter of the laminate that are typically referred to as “frames.” Frames are commonly used in the construction of PV modules in order to provide structural rigidity that is required to resist forces that occur during the transport and installation of PV modules, as well as resist natural forces from wind and snow pressures once a module has been installed on a roof or other type of structure. Common PV frames contain a slot or gap at a top or upper portion of the extrusion, which may at least partially capture, hold, or support a PV laminate. The frame also may contain an aperture or hollow section which may be partially or wholly located below the slot of the upper portion. The hollow section may be sized to accommodate a joining member (commonly referred to as, or termed, a “corner key”) during the module assembly process. Common PV frames suffer from a number of drawbacks. Common PV frames with a single hollow section do not allow for increases in tolerance yields during the extrusion process. Other PV frames do not contain a groove that accepts mounting and/or electrically bonding PV module hardware. Other PV frames do not contain a diagonal wall portion to improve groove stability during some connection methods. What is instead desired is a frame that is conserves material while providing strength and rigidity. Ideally, such a system would also protect laminate edges from bending stresses and have a low side profile. The foregoing examples of the related art and limitations related therewith are intended to be illustrative and not exclusive. Other limitations of the related art will become apparent to those of skill in the art upon a reading of the specification and a study of the figures.

### SUMMARY

The following embodiments and aspects thereof are described and illustrated in conjunction with systems, apparatus, tools, and methods which are meant to be exemplary and illustrative, not limiting in scope. In various embodiments, one or more of the above-described problems have been reduced or eliminated, while other embodiments are directed to other advantages or improvements (including increased strength, laminate protection and low profile design).

One embodiment of the invention comprises components and a method for producing components that, without limitation, frame a PV module such that the frame (i) provides improved stability for the groove incorporated therein, (ii) enables a higher percentage of intolerance final PV module product, and (iii) enables acceptance of a wider tolerance range in raw frame extrusion than the prior art. An embodiment may include a profile with a first hollow and a second hollow, collinear to one another and separated by a diagonal component. A corner key with teeth and male portions may engage the first hollow of adjacent profiles that meet orthogonally. Once so engaged, a tool head may be applied to the corner formed by the adjacent profiles. The application of the tool head may create indentations in the profiles that engage the teeth of the corner keys within the profiles, forming a corner of a PV module frame.

In addition to the exemplary aspects and embodiments described above, further aspects and embodiments will become apparent by reference to the figures and by study of the following detailed descriptions.

### BRIEF DESCRIPTION OF THE DRAWINGS

Demonstrative embodiments are illustrated in referenced figures and drawings. It is intended that the embodiments and figures disclosed herein are to be considered illustrative rather than restrictive.

FIG. 1 is an isometric view of a photovoltaic (“PV”) module.

FIG. 2 is an orthogonal view of a portion of a PV module frame with a single hollow and no groove.

FIG. 3 is an isometric view of a corner key.

FIG. 4 is an orthogonal view of a portion of a PV module frame with an integrated groove and two hollows separated by a diagonal portion.

FIG. 5 is an isometric view of two grooved frame portions aligned with a corner key.

FIG. 6 is an isometric view of a tool head aligned with two grooved frame portions connected to one another by a corner key.

FIG. 7 is an isometric view of a tool head engaging two grooved frame portions connected to one another by a corner key.

FIG. 8 is an isometric view of two grooved frame portions, indented by a tool head, connected to one another by a corner key secured by the tool head indentations.

FIG. 9A is an isometric view of a portion of a PV module frame with an integrated groove and two hollows separated by a diagonal portion.

FIG. 9B is an orthogonal view corresponding to FIG. 9A.

### DETAILED DESCRIPTION OF ONE OR MORE EMBODIMENTS OF THE INVENTION

Terms. With reference to the figures and description herein but without limitation:

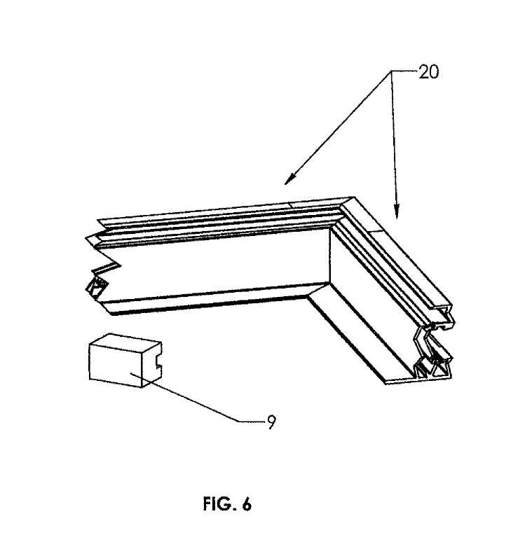

Adjacent refers to being positioned next to or adjoining or neighboring, or having a common vertex or common side. Thus, adjacent PV panels would include PV panels that have one side close to (from a few inches apart to abutting) and facing one side of another PV panel. Sometimes, but not always, the corners of adjacent panels align; so four adjacent panels would have one corner each that nearly or actually touch the other three corners, such as exemplified at FIGS. 6-8 and their descriptions.

Adjustable refers to the capability of being changed so as to match or fit.

Adjustably connected refers to an object, item, mechanism, apparatus, combination, feature, link or the like that loosely, slidable, or rigidly links, interlocks, joins, unites or fastens two or more things together in a manner that can be changed so as to match or fit.

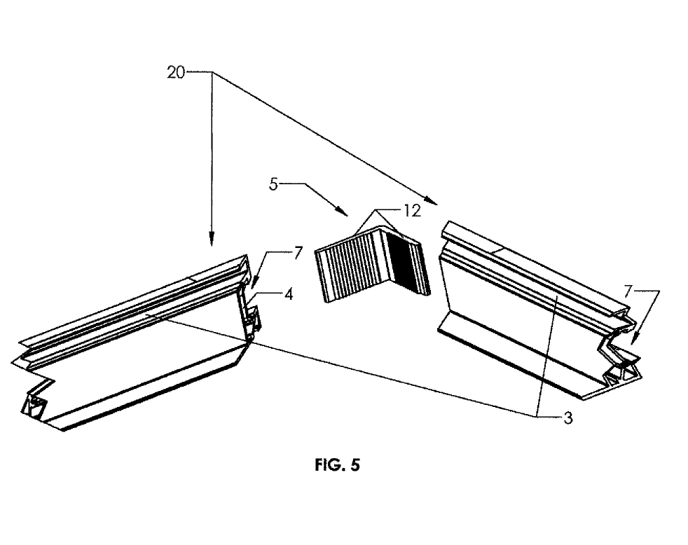

Attach or attachment refers to one or more items, mechanisms, objects, things, structures or the like which are joined, fastened, secured, affixed or connected to another item, or the like in a permanent, removable, secured or non-permanent manner. As an example, a frame portion may be attached to a corner key as exemplified at FIGS. 5-8 and their descriptions.

Beneath refers to extending or being situated directly or substantially underneath, typically with close proximity or contact.

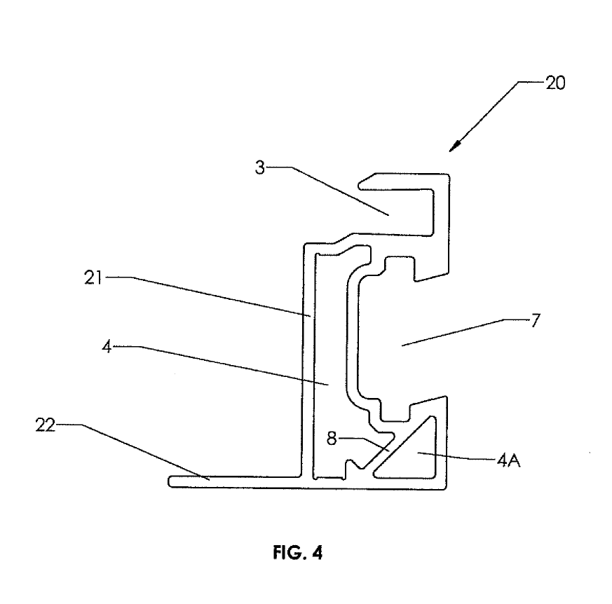

Between refers to being situated, located, or otherwise oriented at, in, or across the space separating two objects or regions. For example, diagonal component 8 is between hollow 4 and hollow 4A in FIG. 4.

Connect or connecting refers to loosely, slidably, or rigidly bringing together or into contact with or joining or fastening to form a link or association between two or more items, mechanisms, objects, things, structures or the like.

Connector refers to an object, item, mechanism, apparatus, combination, feature, link or the like that loosely, slidable, or rigidly links, interlocks, joins, unites or fastens two or more things together. May also include a device, an object, item, mechanism, apparatus, combination, feature, link or the like for keeping two parts of an electric or electronic circuit in contact.

Coplanar refers to the circumstance where two or more objects are situated, located, or otherwise substantially oriented in the same plane.

Couple refers to loosely, slidably, or rigidly joining, linking, interlocking, connecting or mating two or more objects or items, mechanisms, objects, things, structures or the like together.

Coupling refers to an object, item, mechanism, apparatus, combination, feature, link or the like that loosely, slidably, or rigidly joins, links, mates, interlocks, or connects two things together.

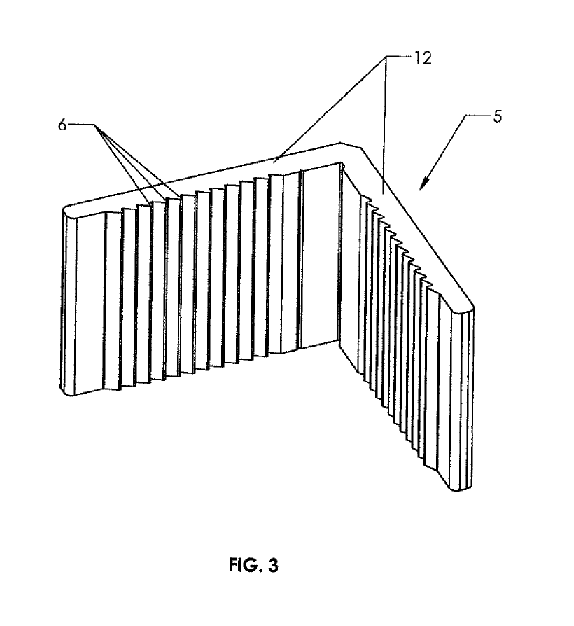

Double male connector refers to a connector (see above) having two male or insertable members, usually used for connecting two female or receiving parts or coupling members together. For example corner key 5 comprises a double male connector as shown in FIG. 3 and its description.

Disengage refers to detaching, freeing, loosening, extricating, separating or releasing from something that holds-fast, connects, couples or entangles. See Engagement below.

Enable refers to facilitating or making possible, able, feasible, practical, operational, or easy; or to cause to operate.

End refers to a final part, termination, extent or extremity of an object, item, mechanism, apparatus, combination, feature, or the like that has a length.

Engage refers to interlocking or meshing or more items, mechanisms, objects, things, structures or the like. See Disengage above.

Frame refers to an essentially rigid structure that surrounds or encloses a periphery of an item, object, mechanism, apparatus, combination, feature, or the like.

Gap refers to a break, void, opening, cleft, breach, aperture, separation, or space, as well as an interruption of continuity, between two objects, or within an object.

Groove refers to a long, narrow cut, rut, indentation, channel, furrow, gutter, slot or depression often used to guide motion or receive a corresponding ridge or tongue.

Insertable refers to an object, item, mechanism, apparatus, combination, feature, link or the like which is capable of being put in, entered into, set within, introduced, inset, inserted, placed, fit or thrust into another an object, item, mechanism, apparatus, combination, feature, link or the like.

Integral with refers to being essential or necessary for completeness, constituent, completing, containing, entire, or forming a unit. It may also refer to consisting or composed of parts that together constitute a whole.

Laminate or PV laminate refers to a photovoltaic device having an interconnected assembly of solar cells, also known as photovoltaic cells which is frequently, but not always, laminated with glass and/or other materials.

Length refers to a measurement or extent of an object, item, mechanism, apparatus, combination, feature, link or the like from end to end, usually along the greater or longer of the two or three dimensions of the body; in distinction from breadth or width.

Located refers to where an object or a series of objects is physically situated with respect to one or more other objects.

Locked refers to fastened, secured or interlocked.

Orthogonally refers to relating to or composed of right angles, perpendicular or having perpendicular slopes or tangents at a point of intersection.

Near refers to a short distance from an object or location.

Perimeter refers to an essentially continuous line forming the boundary, periphery or circuit of a closed geometric figure; the outer limits of an area.

Photovoltaic module (sometimes referred to as a PV module, solar panel, solar module, or photovoltaic panel) refers to a packaged, interconnected assembly of solar cells, also known as photovoltaic cells, frequently, but not always, laminated with glass and other materials and sometimes surrounded by a frame. A plurality of PV modules are commonly used to form a larger photovoltaic system referred to as a PV array (see below), to provide electricity for commercial, industrial and residential applications.

Positionable refers to an object, item, mechanism, apparatus, combination, feature, link or the like which is capable of being positioned, placed or arranged in a particular place or way.

PV laminate refers to a photovoltaic device having an interconnected assembly of solar cells, also known as photovoltaic cells which is frequently, but not always, laminated with glass and/or other materials. A PV laminate with an integral frame which may support the PV laminate is sometimes referred to as a PV module.

PV module (sometimes referred to as a photovoltaic module, solar panel, solar module or photovoltaic panel) refers to a packaged interconnected assembly of solar cells, also known as photovoltaic cells, frequently, but not always, laminated with glass and other materials and sometimes surrounded by a frame. A plurality of PV modules are commonly used to form a larger photovoltaic system referred to as a PV array (see below), to provide electricity for commercial, industrial and residential applications.

PV array refers to a plurality of photovoltaic modules connected together often in a pattern of rows and columns with module sides placed close to or touching other modules.

Rail refers to refers to a relatively straight, usually essentially evenly shaped along its length, rod, beam, girder, profile or structural member or the like, or plurality of such, of essentially rigid material used as a fastener, support, barrier, or structural or mechanical member.

Rail member refers to a structural entity, element or unit (or part of such entity, element, or unit) that acts as or embodies a rail.

Removable refers to one or more items, mechanisms, objects, things, structures or the like which are capable of being removed, detached, dismounted from or taken-away from another item or the like, or combination.

Rectilinear refers to one or more items, mechanisms, objects, things, structures or the like which are essentially bounded by, characterized by or forming straight and substantially parallel lines.

Rigidly couples refers to joining, linking, connecting or mating two or more objects or items, mechanisms, objects, things, components, structures or the like together in a non-flexible manner that is difficult to bend or be forced out of shape.

Roof refers to a structure or protective covering that covers or forms the upper covering or top of a building. The upper surface of a roof is often used as a support surface for mounting, connecting or otherwise attaching a PV module or a PV array.

Rotatably refers to one or more items, mechanisms, objects, things, structures or the like which are capable of being rotated, revolved or turned around or about an axis or center.

Skirt refers to an edging, molding or covering that may be fixed to the edge of a PV module to conceal or block the bottom area under a PV array when the PV array is mounted to a support surface.

Span refers to an extent or measure of space between, or the distance between two points or extremities.

Support or supporting refers to one or more items, mechanisms, objects, things, structures or the like which are capable of bearing weight or other force, often to keep the item or the like from falling, sinking, slipping or otherwise moving out of a position.

Support structure refers to a structure, such as a roof, table or the ground which may provide a base for securing PV modules to form a PV array.

Threaded refers to one or more items, mechanisms, objects, things, structures or the like which have, embody or include an essentially helical or spiral ridge or rib, as on a screw, nut, or bolt.

Various locations refer to places, positions or sites that are different from one another, more than one, individual or separate.

Vertical height adjustment refers to change or adapt to bring items, mechanisms, objects, things, components, structures or the like or components into a proper, desired or preferred relationship of a distance or elevation above a recognized level, such as the ground or a support surface.

Width refers to the state, quality, or fact of being wide or a measurement or extent of something from side to side; in distinction from breadth or length.

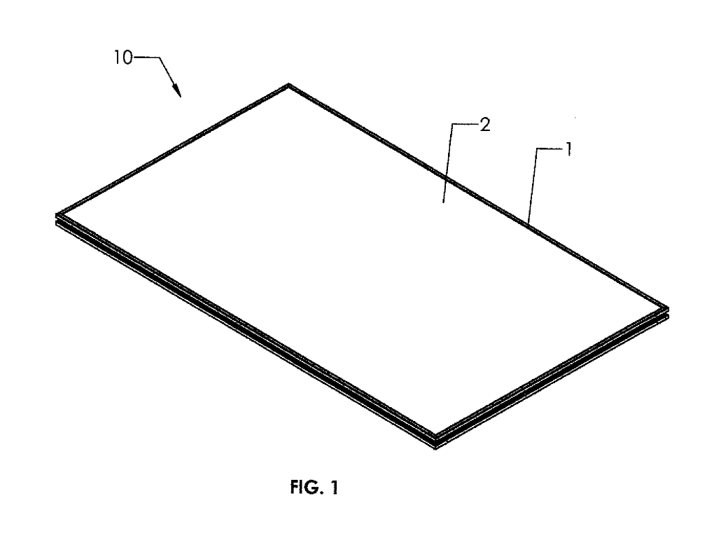

FIG. 1 shows a PV module 10 that is comprised of a laminate 2 containing photovoltaic cells and internal wiring (not shown) with aluminum (or other fabrication material(s), including composites and/or combinations of materials) extrusions 1 located on the perimeter of the laminate that are typically referred to as “frames”. Frames are commonly used in the construction of PV modules in order to provide structural rigidity that is required to resist forces that occur during the transport and installation of PV modules, as well as to resist natural forces from wind and snow pressures once a module has been installed on a roof or other type of structure. Since it is common for PV modules to be rectangular in shape (although other shapes are hereby explicitly contemplated), two separate frame section lengths are commonly used in the assembly of PV modules, one frame length sized based on a long side dimension of a laminate and one frame length sized based on a short side dimension of a laminate.

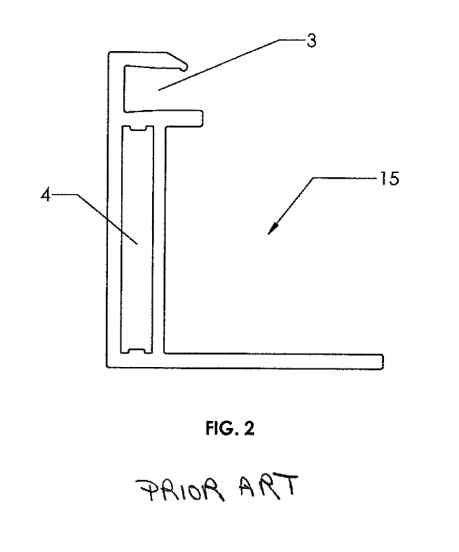

Referring back to FIG. 2, a profile of a common PV module frame is shown. A PV module frame such as frame 15 may include a slot 3 that may capture a portion of a laminate such as laminate 2 as shown and described in FIG. 1. Frame 15 may also include a hollow section 4 that (i) may reduce the amount of material used in the construction of frame 15 to reduce cost and (ii) may be sized to accommodate a male portion as part of the PV module assembly process, discussed in greater detail below.

FIG. 2 shows a cut-away or profile view 15 of a common PV frame extrusion, such as extrusion 1 shown in FIG. 1. As shown in FIG. 2, the profile of the frame contains a slot or gap, such as slot 3 at a top or upper portion of the extrusion, which may at least partially capture, hold, or support a PV laminate. The frame profile also may contain an aperture or hollow section 4, which may be partially or wholly located below slot 3. Hollow section 4 may be sized to accommodate a joining member (commonly referred to as, or termed, a “corner key” and discussed in greater detail below) during the module assembly process.

FIG. 3 shows an example design of one embodiment of a corner key, corner key 5. As shown in FIG. 3, corner key 5 may contain raised ridge features or teeth 6 on their orthogonal inward facing surfaces. Such teeth may have back-faced ridges to resist or inhibit a tongue of key 5 from being withdrawn from a hollow section (such as hollow section 4 of FIG. 2) after insertion. Other embodiments of raised (or lowered) features on a corner key may include cross-hatched ridges (as on a file), dimples, spikes, as well as other forms of teeth, ridges, and the like. A key may also be inserted in a hollow section of a frame extrusion along with a securing member or material (not shown) such as an adhesive fluid or paste, glue, cement or the like and/or an additional high-friction material such as a rubber sheath or fabric, or the like.

Referring to FIG. 3, a corner key is shown. A corner key such as corner key 5 may include one or more male portions 12 each with one or more teeth 6. The instant embodiment of corner key 5 comprises two male portions 12. A male portion 12 may engage a hollow portion 4 in the process of constructing a PV module 10, as discussed in greater detail below.

While it is shown in FIG. 3 that the front-faced teeth have a portion having a specific cut angle, other angles are explicitly contemplated; including but not limited to a front face of 45 degrees and a back face of approximately 90 degrees. However, not all teeth must have the same one or more angles. The front and back faces of the teeth can therefore be angled at 0-20 degrees, 20-30 degrees, 30-45 degrees, 46-60 degrees, 61-75 degrees or 76-90 degrees. In the illustrated embodiment, FIG. 3 shows teeth on a male portion 12 of key 5 with a combination of angles on the front-face of many teeth, being approximately 45 degrees near the top, and approximately 0 degrees proximate the top as well as a back-face having approximately 90 degrees throughout.

Frame members may be cut at a 45 degree angle to join the corners of frames around a laminate in a mitered fashion. The joining of two frames with a corner-key inserted into each of the frames, such as into pre-formed hollow section, at a corner of the frame provides a rigid connection that resists separation due to tensile and compressive loading that may occur, such as due to PV module installation or deflection from natural forces. In addition to providing a structural connection, the joining of frame corners by insertion of a corner-key also may provide an electrical bonding path between separate frame members, which may be used for grounding or other electrical purposes.

FIG. 4 shows an embodiment of a frame profile 20 that contains a groove 7 on the outside surface of the frame in addition to the laminate slot 3 and hollow section 4 for corner key insertion that are found in prior art frames, such as the one depicted in FIG. 2, above. The unique geometry present in groove 7 may be used to accept mounting and/or electrically bonding PV module hardware, as described in previous patent applications of common assignment and at least one common inventor, including but not limited to U.S. Pat. Nos. 7,592,537 and 8,109,048, as well as published applications: US2010/0065108, US2011/0000526, and US2012/0152326; all incorporated herein in their entireties. In order to functionally interoperate with various hardware devices or items, critical feature dimensions and tolerances are designated for the groove 7. In addition, a limited range of spring rate or stiffness for the groove 7 shape may be designated to ensure ease of installation for mating components and proper retention of hardware, especially when under PV module loading.

Frame corners may be joined in one or more manners, processes or methods (usually referred to as methods herein); although two separate and distinct representative methods are herein disclosed, other methods and combinations of methods are contemplated as will occur to those skilled in the art. The first method relies on the use of fasteners, such as thread forming screws, inserted into female (such as “boss”) features located within a frame's extrusion profile. Such a fastener corner joining method is usually difficult to automate and requires post operation machining steps for the addition of screw head counter bores. In addition, the requirement for female boss features located within a frame's extrusion profile may result in an excessive and non-structurally optimized amount of frame material being required.

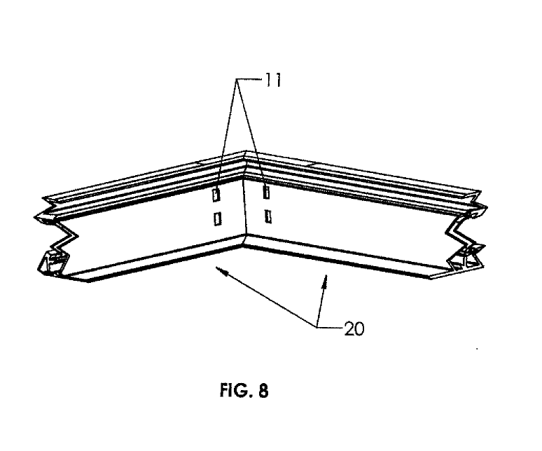

The second example method of joining frame corners uses a process often termed “corner crimping”; this process is also commonly employed in the construction of screen windows and doors. As shown in FIGS. 5-8, during a corner crimping process, two miter-cut lengths of a frame are joined together while a corner key is inserted into a hollow section located within a frame extrusion's profile. A manufacturing assembly process tool, commonly termed a “framing table” is used to press the frame sections onto a laminate, so that the laminate is retained within slot 3 located within the frame profile. A manual, mechanical, hydraulic, motor, or otherwise powered or driven actuator is then used to force a tool head 9 onto the orthogonal inside surfaces of the joined miter cut frame corner. This tool head is commonly referred to as a “crimping head”. The force exerted by the crimping head causes the inside surfaces of the joined frames to deform in the locations where applied force is concentrated. This deformation forces at least some of the frame material to be relocated into the ridge features 6 on corner key surface, thus providing a rigid structural (and electrically, if desired) bonded corner connection. FIG. 8 shows indentation pattern features 11 that may be formed on the inside surface of one or more of the frame members after the crimping process has occurred.

Maintaining the critical feature dimensions and tolerances within the groove 7 shown in FIG. 4 during the extrusion of the frame may result in lower extrusion yields than typically experienced during this manufacturing process, which in turn results in higher cost per length of frame. In addition, during the crimping process described previously, the critical groove 7 dimensions may also be distorted due to the forces exerted on the orthogonal inside surfaces of the joined frame corner.

It is therefore an advantage of the present system to possess a frame profile design that may allow for increases in tolerance yields during the extrusion process in addition to permitting for critical groove 7 dimensions to remain within tolerance during a corner key crimping process. It is a further advantage of the present system to structurally optimize the profile design of an extrusion in order to reduce the use of material while still maintaining required strength for torsional and deflection loading.

Referring to FIG. 4, a profile of a portion of a grooved frame is shown. A frame such as frame 20 may include a groove 7, a slot 3, a hollow section 4, a second hollow portion 4A that may be collinear with hollow section 4, and a diagonal wall portion 8, alternatively identified as a diagonal component. Frame 20 may frame a PV module. Frame 20 may further include a vertical component 21 and a horizontal component 22. Vertical component 20, horizontal component 22, and the interior surface of groove 7 may enclose hollow section 4 and hollow section 4A. Diagonal component 8 may enable higher in-tolerance yields during the extrusion process in circumstances where frame 20 is produced via extrusion. Diagonal component 8 may improve the stability of groove 7 by providing structural support that is absent from a grooved frame with a single hollow portion 4.

As shown in FIG. 4, an embodiment of a novel frame profile 20 may contain a diagonal wall portion 8 that results in two hollow portions 4 and 4a within the profile. Dual hollow frame 20 may enable higher in-tolerance yields during the extrusion process when compared to single-hollow frames. The addition of diagonal wall portion 8 in frame profile also produces improved groove 7 stability during some connection methods, such as a corner key crimping process. Therefore, frame 20 may enable a higher percentage of in-tolerance final PV module product and the ability for acceptance of a wider tolerance range in raw frame extrusion. In addition, in many instances, a reduction in aluminum material (or other fabrication material) may be achieved when compared to alternate single hollow frame designs due to structural optimization for torsion and deflection resulting from the increased area moment of inertia provide by frame 20.

Referring now to FIG. 5, an isometric view of two frame portions and a corner key are shown. Each frame portion 20 is aligned with a male portion 12 of corner key 5. The frame portions 20 and corner keys 5 are aligned such that (i) each male portion 12 aligns with the hollow portion 4 of each frame 20 and (ii) the grooves 7 of each frame 20 face outward.

Referring now to FIG. 6, an isometric view of two frame portions and a tool head is shown. The two frame sections 20 are shown connected to a corner key 5 (not shown) and aligned with tool head 9.

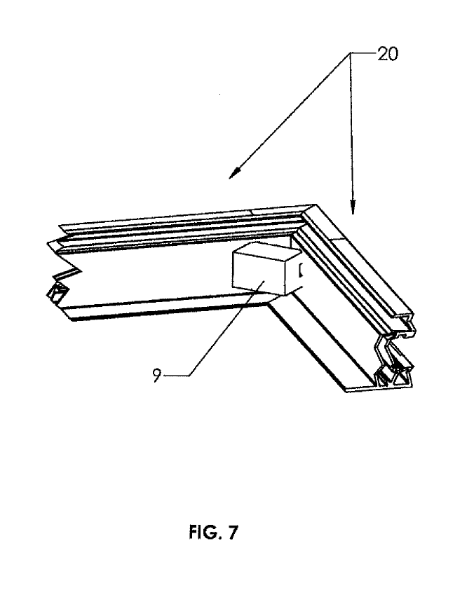

Referring now to FIG. 7, an isometric view of a tool head being applied to two frame portions is shown. Frame portions 20 are connected to a corner key 5 (not shown), and the tool head 9 is forcibly applied to the inside surfaces of the frame portions 20 as shown to create indentations (not shown) on which the teeth 9 (not shown) of the corner key 5 (not shown) catch to secure the frame portions 20 to one another.

Referring now to FIG. 8, two frame portions are shown connected to one another. Frame portions 20 connect to a corner key 5 (not shown) as detailed above and indentations 11 caused by the application of the tool head 9 (not shown) are visible on the frame portions 12. Indentations 11 provide resistance against teeth 6, thereby firmly securing the corners of the frame together.

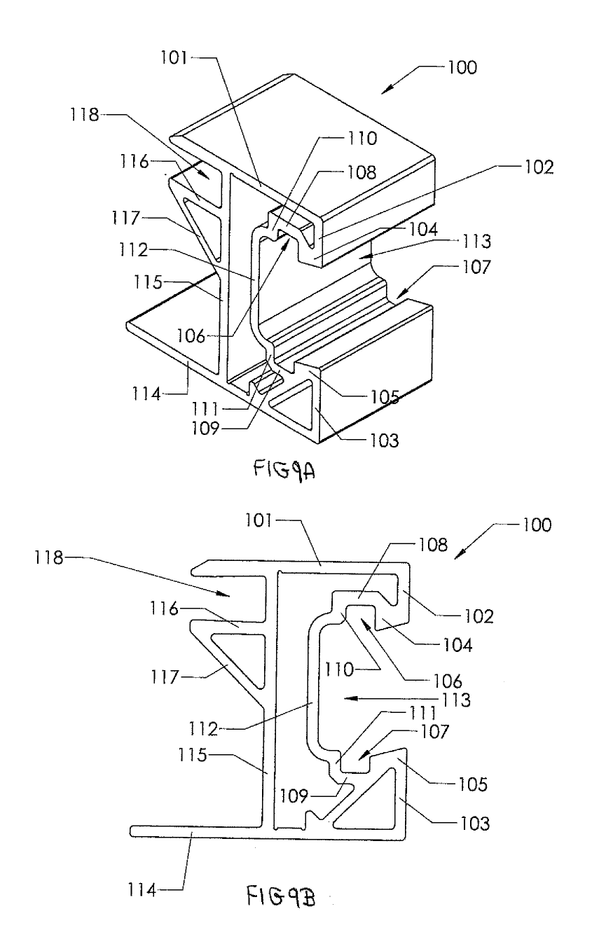

Referring now to FIGS. 9A and 9B, a frame member 100 is provided. Frame member 100 has a top panel 101, an upper outside panel 102, a lower outside panel 103, an upper lip 104, a lower lip 105, an upper recess 106, a lower recess 107, an upper groove surface 108, a lower groove surface 109, an upper wall recess 110, a lower wall recess 111, an inside groove wall 112, and a groove 113. Taken together, features 102, 104, 112, 105 and 103 form an outer grooved structure, defining a side groove.

Also included are an inside panel 115, a horizontal support panel 116, and a diagonal support panel 117. The arrangement of top panel 101, inside panel 115, and horizontal panel 116 forms a laminate channel 118. A hollow section is formed between the inside panel and the outer grooved structure. The optional lower diagonal portion between lower lip 105 and bottom panel 114 divides the hollow section into two hollow sections (similar to wall portion 8 in FIG. 4).

Frame member 100 may be made of aluminum, steel, or any suitable metal, and it may be forged, molded, extruded or made by any other method.

An advantage of the embodiment seen in FIGS. 9A and 9B (as compared to the embodiment of FIG. 4) is that the embodiment of FIGS. 9A and 9B provides comparable (or improved) strength and rigidity, while achieving this with a lower profile frame section. This is achieved because the laminate is received into the slot 3 in FIG. 4, whereas the laminate is received into the slot 118 in FIG. 9B. Therefore, in the embodiment of FIG. 4, the edge of the laminate is positioned directly above the groove 7. In contrast, in the embodiment of FIG. 9B, the laminate edge is not positioned directly above groove 113. Rather, the edge of the laminate is supported from below by panel 116, which is in turn supported from below by panel 117. Thus, the overall height of the frame embodiment in FIGS. 9A/9B is lower than that of FIG. 4. Secondly, the edge of the laminate in FIG. 9A/9B is recessed from the edge of the frame. This shields the laminate edges from bending stresses applied at the groove during installation. Third, the addition of panel 101 which spans over the groove 113 prevents bending stresses from being applied to the laminate edges. Fourth, diagonal panel 117 provides support below the laminate. In contrast, in FIG. 4, the laminate is supported by the same structure that forms the top of the groove. Therefore, since the embodiment of FIG. 8 has a lower profile, it uses less material to make than the embodiment in FIG. 4.

While a number of exemplary aspects and embodiments have been discussed above, those of skill in the art will recognize certain modifications, permutations, additions and sub-combinations thereof. It is therefore intended that the following appended claims and claims hereafter introduced be interpreted to include all such modifications, permutations, additions, and sub-combinations as are within their true spirit and scope.

What is claimed is:

1. A photovoltaic module frame, comprising:
(a) a top panel;
(b) a bottom panel;
(c) an inside panel connecting the top and bottom panels;
(d) an outer grooved structure connecting the top and bottom panels, wherein a hollow section is formed between the inside panel and the outer grooved structure; and
(e) a support panel extending from the inside panel to form a laminate receiving slot between the top panel and the support panel.

2. The photovoltaic module frame of claim 1, further comprising:
(f) a panel extending from the bottom panel to the outer grooved structure, thereby forming a second hollow section between the bottom panel and the outer grooved structure.

3. The photovoltaic module frame of claim 2, wherein the panel extending from the bottom panel to the outer grooved structure extends in a diagonal direction.

4. The photovoltaic module frame of claim 1, wherein the laminate receiving slot is not disposed above the hollow section formed between the inside panel and the outer grooved structure.

5. The photovoltaic module frame of claim 1, wherein the laminate receiving slot is disposed beside the hollow section formed between the inside panel and the outer grooved structure.

6. An assembly of two photovoltaic module frames held together by a corner key, comprising:
(a) a first frame, comprising:
(i) a top panel;
(ii) a bottom panel;
(iii) an inside panel connecting the top and bottom panels;
(iv) an outer grooved structure connecting the top and bottom panels, wherein a hollow section is formed between the inside panel and the outer grooved structure; and
(v) a support panel extending from the inside panel to form a laminate receiving slot between the top panel and the support panel;
(b) a second frame, comprising:
(i) a top panel;
(ii) a bottom panel;
(iii) an inside panel connecting the top and bottom panels;
(iv) an outer grooved structure connecting the top and bottom panels, wherein a hollow section is formed between the inside panel and the outer grooved structure; and
(v) a support panel extending from the inside panel to form a laminate receiving slot between the top panel and the support panel;
wherein the first and second frames are positioned at an angle to one another; and
(c) a corner key having a first male portion received in the hollow section in the first frame and a second male portion received in the hollow section in the second frame.

7. The assembly of claim 6, wherein the first and second male portions of the corner key are disposed at right angles to one another.

8. The assembly of claim 6, wherein the first and second male portions of the corner key have raised protrusions thereon.

9. The assembly of claim 8, wherein the first and second frames are crimped against the raised protrusions on the first and second male portions of the corner key.
